(19) United States
(12) Patent Application Publication
(10) Pub. No.: US 2007/0238301 A1
(43) Pub. Date: Oct. 11, 2007

(54) Batch processing system and method for performing chemical oxide removal

(76) Inventors: Stephen H. Cabral, Pine Plains, NY (US); Aelan Mosden, Poughkeepsie, NY (US); Young Jong Lee, Fishkill, NY (US)

Correspondence Address: DLA PIPER US LLP, P. O. BOX 9271, RESTON, VA, 20195, US

(21) Appl. No.: 11/390,470

(22) Filed: Mar. 28, 2006

(51) Int. Cl. H01L 21/461; H01L 21/302

(52) U.S. Cl. 438/706; 438/714; 438/723; 438/743

(57) ABSTRACT

A batch processing system and method for chemical oxide removal (COR) is described. The batch processing system is configured to provide chemical treatment of a plurality of substrates, wherein each substrate is exposed to a gaseous chemistry, such as HF/NH₃, under controlled conditions including surface temperature and gas pressure. Furthermore, the batch processing system is configured to provide thermal treatment of a plurality of substrates, wherein each substrate is thermally treated to remove the chemically treated surfaces on each substrate.

### CROSS-REFERENCE TO RELATED APPLICATIONS

This application is related to co-pending U.S. patent application Ser. No. 10/705,200, entitled “Processing System and Method for Chemically Treating a Substrate”, Attorney docket no. 071469/0306773, filed on Nov. 12, 2003; co-pending U.S. patent application Ser. No. 10/704,969, entitled “Processing System and Method for Thermally Treating a Substrate”, Attorney docket no. 071469/0306775, filed on Nov. 12, 2003; and co-pending U.S. patent application Ser. No. 10/705,201, entitled “Processing System and Method for Treating a Substrate”, Attorney docket no. 071469/0306772, filed on Nov. 12, 2003. The entire contents of all of these applications are herein incorporated by reference in their entirety.

### BACKGROUND OF THE INVENTION

1. Field of the Invention

The present invention relates to a system and method for treating a plurality of substrates, and more particularly to a system and method for chemical and thermal treatment of a plurality of substrates.

2. Description of Related Art

In material processing methodologies, pattern etching comprises the application of a thin layer of light-sensitive material, such as photoresist, to an upper surface of a substrate, that is subsequently patterned in order to provide a mask for transferring this pattern to the underlying thin film during etching. The patterning of the light-sensitive material generally involves exposure by a radiation source through a reticle (and associated optics) of the light-sensitive material using, for example, a micro-lithography system, followed by the removal of the irradiated regions of the light-sensitive material (as in the case of positive photoresist), or non-irradiated regions (as in the case of negative resist) using a developing solvent.

Additionally, multi-layer and hard masks can be implemented for etching features in a thin film. For example, when etching features in a thin film using a hard mask, the mask pattern in the light-sensitive layer is transferred to the hard mask layer using a separate etch step preceding the main etch step for the thin film. The hard mask can, for example, be selected from several materials for silicon processing including silicon dioxide (SiO₂), silicon nitride (Si₃N₄), and carbon, for example.

In order to reduce the feature size formed in the thin film, the hard mask can be trimmed laterally using, for example, a two-step process involving a chemical treatment of the exposed surfaces of the hard mask layer in order to alter the surface chemistry of the hard mask layer, and a post treatment of the exposed surfaces of the hard mask layer in order to desorb the altered surface chemistry.

### SUMMARY OF THE INVENTION

The present invention relates to a system and method for treating a plurality of substrates, and to a system and method for chemically and thermally treating a plurality of substrates.

Any of these and/or other aspects may be provided by a processing system for treating an oxide film in accordance with the present invention. In one embodiment, the processing system for etching or removing an oxide film on a plurality of substrates comprises a process chamber configured to contain the plurality of substrates, one or more of the plurality of substrates having the oxide film thereon. A substrate holder is coupled to the process chamber and configured to support the plurality of substrates. A chemical treatment system is coupled to the process chamber and configured to introduce a process gas comprising as incipient ingredients HF and optionally ammonia (NH₃) to the process chamber, wherein the process gas chemically alters exposed surface layers on the plurality of substrates. A thermal treatment system is coupled to the process chamber and configured to elevate the temperature of the plurality of substrates, wherein the elevated temperature causes evaporation of the chemically altered surface layers. A controller is configured to control the amount of the process gas introduced to the plurality of substrates, and the temperature to which the plurality of substrates are heated.

In another embodiment, a method and computer readable medium for etching an oxide film on a plurality of substrates comprises disposing the plurality of substrates in a batch processing system. The plurality of substrates are chemically treated by exposing them to a gas composition including as incipient ingredients HF and optionally ammonia (NH₃). The plurality of substrates are thermally treated by heating them.

### BRIEF DESCRIPTION OF THE DRAWINGS

In the accompanying drawings:

FIG. 1 presents a block diagram batch processing system for performing a chemical oxide removal process according to an embodiment of the present invention;

FIG. 2 presents a batch processing system for performing a dry, non-plasma chemical removal process according to another embodiment of the present invention;

FIG. 3 presents a batch processing system for performing a dry, non-plasma chemical removal process according to another embodiment of the present invention;

FIG. 4 presents a batch processing system for performing a dry, non-plasma chemical removal process according to another embodiment of the present invention; and

FIG. 5 presents a flow chart of a method of performing a dry, non-plasma chemical removal process according to an embodiment of the present invention.

### DETAILED DESCRIPTION OF EXEMPLARY EMBODIMENTS

In the following description, for purposes of explanation and not limitation, specific details are set forth, such as a particular geometry of the processing system and descriptions of various components. However, it should be understood that the invention may be practiced in other embodiments that depart from these specific details.

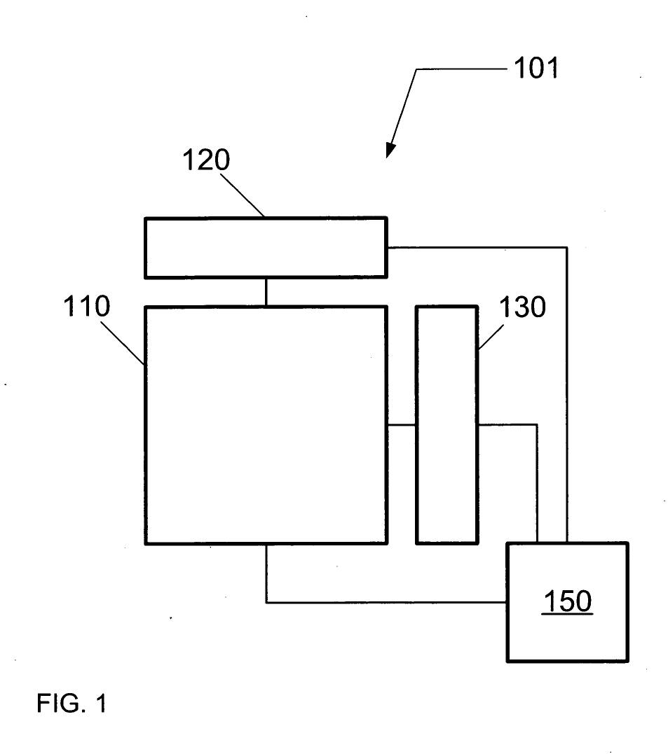

According to one embodiment, FIG. 1 presents a processing system 101 for processing a plurality of substrates using a dry, non-plasma, chemical removal process, such as a chemical oxide removal process, to, for example, trim an oxide mask or remove native oxide or remove a SiOₓ, containing residue. FIG. 1 presents a block diagram of a processing system 101 for treating the oxide film on a plurality of substrates. Processing system 101 includes a process chamber 110 configured to process the plurality of substrates, a chemical treatment system 120 coupled to the process chamber 110 and configured to introduce a process gas to the plurality of substrates mounted in process chamber 110, a thermal treatment system 130 coupled to process chamber 110 and configured to elevate the temperature of the plurality of substrates, and a controller 150 coupled to the process chamber 110, the chemical treatment system 120 and the thermal treatment system 130, and configured to control the processing system 101 according to a process recipe.

For example, the chemical treatment system is configured to introduce a process gas comprising a first gaseous component having as an incipient ingredient HF and an optional second gaseous component having as an incipient ingredient ammonia (NH₃). The two gaseous components may be introduced together, or independently of one another. Additionally, either gaseous component, or both, can be introduced with a carrier gas, such as an inert gas. The inert gas can comprise a Noble gas, such as argon. The chemical treatment of the oxide film on the plurality of substrate by exposing this film to the two gaseous components causes a chemical alteration of the oxide film surface to a self-limiting depth. The thermal treatment system 130 can elevate the temperature of the plurality of substrates to a temperature range from approximately 50 degrees C. to approximately 450 degrees C., and desirably, the substrate temperature can range from approximately 100 degrees C. to approximately 300 degrees C. For example, the substrate temperature may range from approximately 100 degrees C. to approximately 200 degrees C. The thermal treatment of the chemically altered oxide surface layers causes the evaporation of these surface layers.

Furthermore, the chemical treatment system 120 can further include a temperature control system for elevating the temperature of the vapor delivery system in order to prevent the condensation of process vapor therein. The process chamber 110 can further include a substrate holder for mounting the plurality of substrates that may be stationary, translatable, or rotatable.

Controller 150 includes a microprocessor, memory, and a digital I/O port (potentially including D/A and/or A/D converters) capable of generating control voltages sufficient to communicate and activate inputs to the process chamber 110, the chemical treatment system 120 and the thermal treatment system as well as monitor outputs from these systems. A program stored in the memory is utilized to interact with the systems 120 and 130 according to a stored process recipe.

Alternately, or in addition, controller 150 can be coupled to a one or more additional controllers/computers (not shown), and controller 150 can obtain setup and/or configuration information from an additional controller/computer.

In FIG. 1, singular processing elements (120 and 130) are shown, but this is not required for the invention. The processing system 101 can comprise any number of processing elements having any number of controllers associated with them in addition to independent processing elements.

The controller 150 can be used to configure any number of processing elements (120 and 130), and the controller 150 can collect, provide, process, store, and display data from processing elements. The controller 150 can comprise a number of applications for controlling one or more of the processing elements. For example, controller 150 can include a graphic user interface (GUI) component (not shown) that can provide easy to use interfaces that enable a user to monitor and/or control one or more processing elements.

The processing system 101 can also comprise a pressure control system (not shown). The pressure control system can be coupled to the processing chamber 110, but this is not required. In alternate embodiments, the pressure control system can be configured differently and coupled differently. The pressure control system can include one or more pressure valves (not shown) for exhausting the processing chamber 110 and/or for regulating the pressure within the processing chamber 110. Alternately, the pressure control system can also include one or more pumps (not shown). For example, one pump may be used to increase the pressure within the processing chamber, and another pump may be used to evacuate the processing chamber 110. In another embodiment, the pressure control system can comprise seals for sealing the processing chamber.

Furthermore, the processing system 101 can comprise an exhaust control system. The exhaust control system can be coupled to the processing chamber 110, but this is not required. In alternate embodiments, the exhaust control system can be configured differently and coupled differently. The exhaust control system can include an exhaust gas collection vessel (not shown) and can be used to remove contaminants from the processing fluid. Alternately, the exhaust control system can be used to recycle the processing fluid.

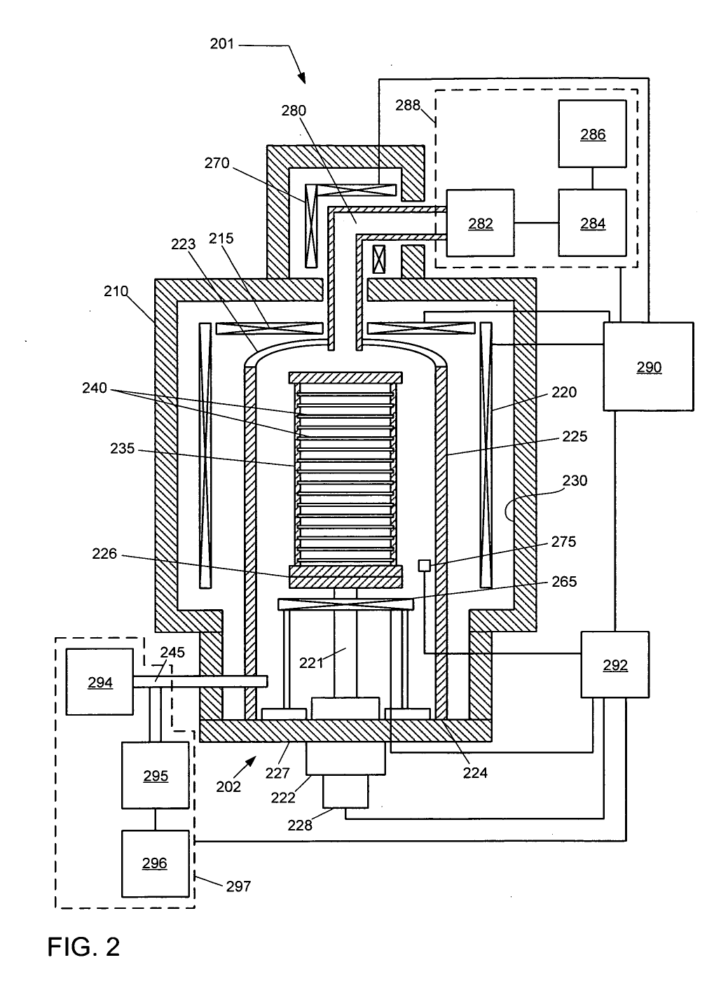

Referring now to FIG. 2, a simplified block diagram of a batch processing system is shown according to another embodiment. The batch processing system 201 contains a process chamber 210 and a process tube 225 that has an upper end 223 connected to an exhaust system 288 via an exhaust duct 280, and a lower end 224 hermetically joined to a lid 227 of cylindrical manifold 202. The exhaust duct 280 discharges gases from the process tube 225 to exhaust system 288 to maintain a pre-determined pressure, e.g., atmospheric or below atmospheric pressure, in the processing system 201. A substrate holder 235 for holding a plurality of substrates (wafers) 240 in a tier-like manner (in respective horizontal planes at vertical intervals) is placed in the process tube 225. The substrate holder 235 resides on a turntable 226 that is mounted on a rotating shaft 221 penetrating the lid 227 and driven by a drive system 228 (which may comprise an electric motor). The turntable 226 can be rotated during processing to improve overall film uniformity or, alternately, the turntable can be stationary during processing. The lid 227 is mounted on an elevator 222 for transferring the substrate holder 235 in and out of the process tube 225. When the lid 227 is positioned at its uppermost position, the lid 227 is adapted to close the open end of the manifold 202.

A chemical treatment system 297 is configured for introducing a process gas comprising a first gaseous component including as an incipient ingredient HF and an optional second gaseous component including as an incipient ingredient ammonia (NH₃) to process chamber 210, with or without an additional carrier gas. A plurality of gas supply lines can be arranged around the manifold 202 to supply a plurality of gases into the process tube 225 through the gas supply lines. The two gaseous components may be introduced together, or independently of one another. In FIG. 2, only one gas supply line 245 among the plurality of gas supply lines is shown. The gas supply line 245 (as shown) is connected to a process gas source 294. In general, the process gas source 294 can supply process gases for processing the substrates 240, including, gases for a dry, non-plasma, chemical removal process, such as chemical oxide removal. For example, a chemical oxide removal process includes a dry chemical process whereby an oxide film is exposed to a process gas comprising as incipient ingredients HF and ammonia, concurrently with or followed by thermal treatment to evaporate the chemically altered surface layer on the oxide film. Additionally, chemical treatment system 297 may further comprise an additional process gas source 296 and a remote plasma source 295 configured to produce radicals or fragmented molecules of the process gas from process gas source 296. The introduction of gaseous radicals to process chamber 210 can facilitate other processes, such as etching processes and ashing or stripping process, that may be used in conjunction with the dry, non-plasma process described herein.

A cylindrical heat reflector 230 is disposed so as to surround the reaction tube 225. For example, the cylindrical heat reflector 230 may be disposed within the inner surface of process chamber 210. The heat reflector 230 has a mirror-finished inner surface to suppress dissipation of radiation heat radiated by the thermal treatment system including a main heater 220, a bottom heater 265, a top heater 215, and an exhaust duct heater 270. A helical cooling water passage (not shown) may be formed in the wall of the process chamber 210 as a cooling medium passage.

The exhaust system 288 comprises a vacuum pump 286, a trap 284, and automatic pressure controller (APC) 282. The vacuum pump 286 can, for example, include a dry vacuum pump capable of a pumping speed up to 20,000 liters per second (and greater). During processing, gases can be introduced into the process chamber 210 via the gas supply line 245 of the fluid distribution system 297 and the process pressure can be adjusted by the APC 282. The trap 284 can collect by-products from the process chamber 210.

The process monitoring system 292 comprises a sensor 275 capable of real-time process monitoring and can, for example, include a mass spectrometer (MS), a Fourier transform infra-red (FTIR) spectrometer, or a particle counter. A controller 290 includes a microprocessor, a memory, and a digital I/O port capable of generating control voltages sufficient to communicate and activate inputs to the batch processing system 201 as well as monitor outputs from the batch processing system 201. Moreover, the controller 290 is coupled to and can exchange information with fluid distribution system 297, drive system 228, process monitoring system 292, thermal treatment system 220, 215, 265, and 270, and exhaust system 288. The controller 290 may be implemented as a DELL PRECISION WORKSTATION 610™.

The controller 290 may also be implemented as a general purpose computer, processor, digital signal processor, etc., which causes a substrate processing apparatus to perform a portion or all of the processing steps of the invention in response to the controller 290 executing one or more sequences of one or more instructions contained in a computer readable medium. The computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

The controller 290 may be locally located relative to the batch processing system 201, or it may be remotely located relative to the batch processing system 201 via an internet or intranet. Thus, the controller 290 can exchange data with the batch processing system 201 using at least one of a direct connection, an intranet, and the internet. The controller 290 may be coupled to an intranet at a customer site (i.e., a device maker, etc.), or coupled to an intranet at a vendor site (i.e., an equipment manufacturer). Furthermore, another computer (i.e., controller, server, etc.) can access controller 290 to exchange data via at least one of a direct connection, an intranet, and the internet.

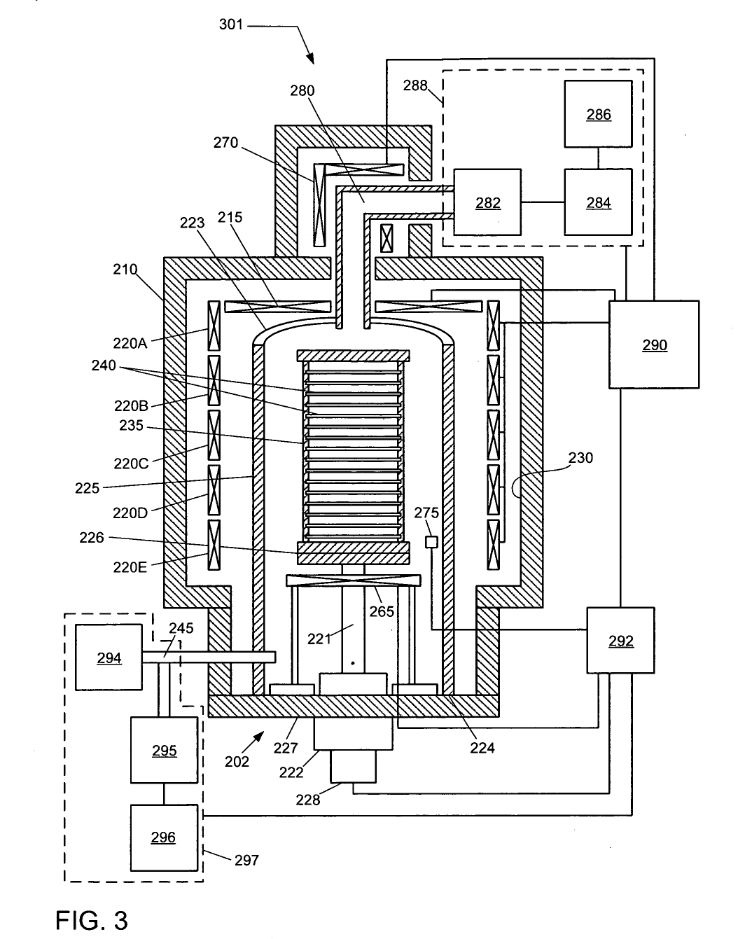

Referring now to FIG. 3, a simplified block diagram of a batch processing system is shown according to another embodiment. The batch processing system 301 contains many of the same features as batch processing system 201 illustrated in FIG. 2 and described above. However, batch processing system 301 further comprises a thermal treatment system having a multiple zone main heater having heating elements 220A, 220B, 220C, 220D and 220E. Although, five (5) heating elements are illustrated, the number of heating elements may vary, e.g., the number may be more or less. Each heating element may comprise a carbon resistive heating element, or other conventional resistive heating element. Additionally, the configuration, or geometry, or both the configuration and geometry of the heating elements may vary from that illustrated in FIG. 3. The multiple zone main heater can facilitate additional control of spatial variations in substrate temperature throughout the batch of substrates. For example, the multiple zone main heater can achieve a heating ramp rate of up to approximately 40 degrees C. per minute, with a temperature controllability of plus or minus 1 degree C.

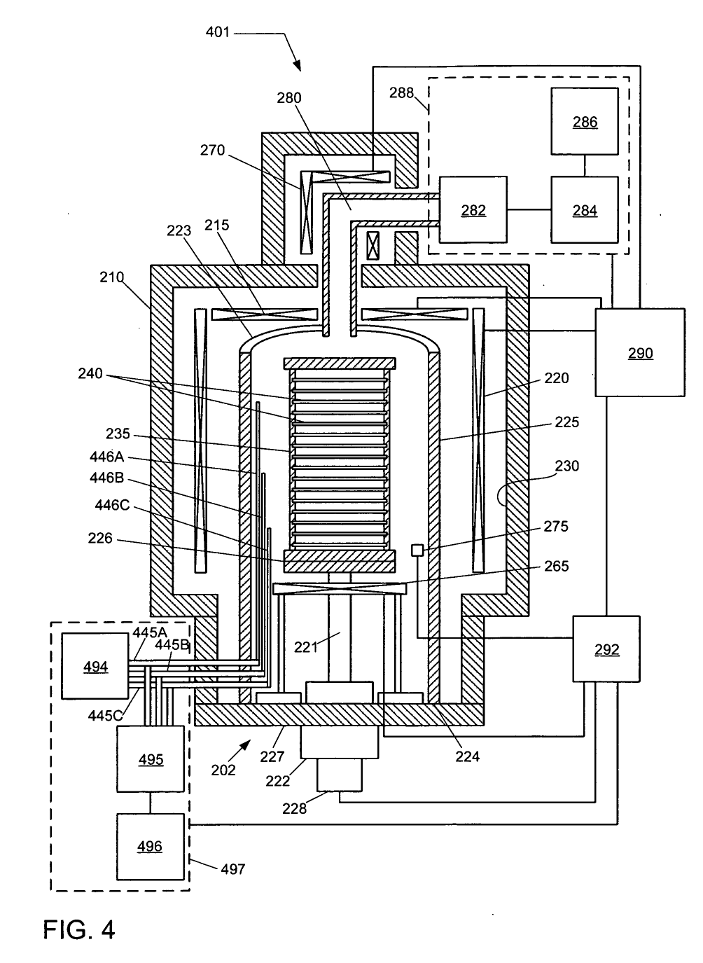

Referring now to FIG. 4, a simplified block diagram of a batch processing system is shown according to another embodiment. The batch processing system 401 contains many of the same features as batch processing system 201 illustrated in FIG. 2 and described above. However, batch processing system 401 further comprises a multiple zone gas injection system comprising a plurality of gas supply lines 445A, 445B and 445C providing a flow of process gas to a plurality of zones along substrate holder 235 via a plurality of gas injection devices 446A, 446B and 446C. Each gas injection device 446A-C may include one or more gas injection orifices of varying size or distribution, or both, along each gas injection device. Any flow property, including the concentration of process gas, flow rate of process gas, etc., may be varied or controlled to each region of the process chamber 210.

It is to be understood that the batch-type processing systems 201, 301, and 401 depicted in FIGS. 2, 3, and 4 are shown for exemplary purposes only, as many variations of the specific hardware can be used to practice the present invention, and these variations will be readily apparent to one having ordinary skill in the art. The batch processing systems 201, 301 and 401 in FIGS. 2, 3 and 4 can, for example, process substrates of any size, such as 200 mm substrates, 300 mm substrates, or even larger substrates. Furthermore, the batch processing systems 201, 301 and 401 can simultaneously process up to about 200 substrates, or more. Alternately, the processing system can simultaneously process up to about 25 substrates. In addition to semiconductor substrates, e.g., silicon wafers, the substrates can, for example, comprise LCD substrates, glass substrates, or compound semiconductor substrates. Components from any of processing system 201, 301 or 401 may be employed in any of the other processing systems.

An exemplary vapor transport-supply apparatus is described in U.S. Pat. No. 5,035,200, assigned to Tokyo Electron Limited, which is incorporated herein by reference in its entirety. Additionally, an exemplary vapor transport-supply apparatus may include a TELFormula® batch processing system, commercially available from Tokyo Electron Limited.

In one example, part of or all of an oxide film, such as a native oxide film, is removed on a plurality of substrates using a chemical oxide removal process. In another example, part of or all of an oxide film, such as an oxide hard mask, is trimmed on a plurality of substrates using a chemical oxide removal process. The oxide film can comprise silicon dioxide (SiO₂), or more generally, SiOₓ, for example. In yet another example, part or all of a SiOₓ-containing residue is removed on a plurality of substrates.

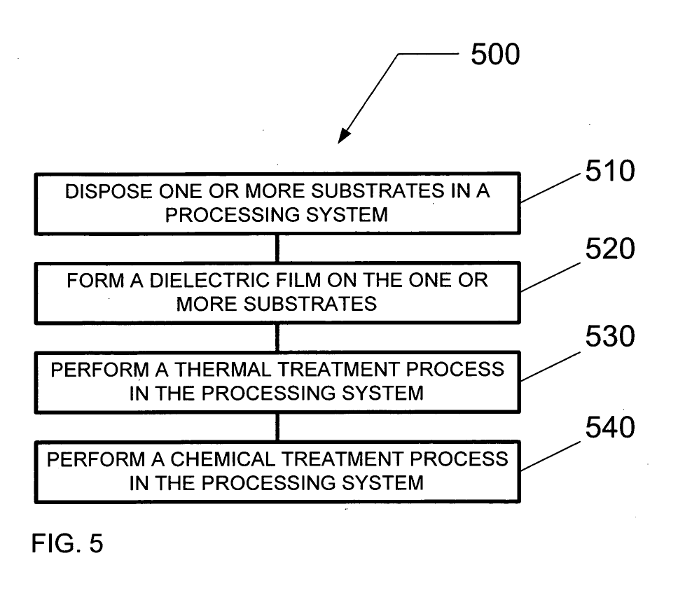

Referring now to FIG. 5, a method of removing part or all of an oxide film or SiOₓ-containing residue or other residue on a plurality of substrates is described. The method is described in a flow chart 500 beginning at 510 with disposing one or more substrates in a process chamber configured to perform a dry, non-plasma, chemical removal process, such as a chemical oxide removal process. The processing system can include any one of the processing systems illustrated in FIG. 1, 2, 3 or 4.

In 520, a chemical treatment process is performed to chemically alter a part or all of the oxide film or residual film on the plurality of substrates. The chemical treatment includes exposing the plurality of substrates to a process gas comprising as incipient ingredients HF and optionally ammonia (NH₃). The two gaseous components may be introduced together (e.g., fully or partially mixed), or independently of one another (e.g., unmixed). The process chamber is evacuated, and the process gas comprising as incipient materials HF and optionally NH₃ is introduced. For example, when etching silicon oxide (SiOₓ), a combination of HF and NH₃ are used. Alternately, the process gas can further comprise a carrier gas. The carrier gas can, for example, comprise an inert gas such as argon, xenon, helium, etc. Additionally, the carrier gas may be utilized to adjust the amount of or rate of oxide removal or residue removal during the process. For additional details, see pending U.S. patent application Ser. No. 10/812,347, entitled “Processing System and Method for Treating a Substrate”, and pending U.S. patent application Ser. No. 10/812,355, entitled “Method and System for Adjusting a Chemical Oxide Removal Process Using Partial Pressure”; the entire contents of each of these applications are herein incorporated by reference in their entirety.

The processing pressure can range from approximately 1 to approximately 10000 mTorr. Alternatively, the processing pressure can range from approximately 2 to approximately 1000 mTorr. Alternatively, the processing pressure can range from approximately 5 mTorr to approximately 500 mTorr. The process gas flow rates can range from approximately 1 to approximately 10000 sccm for each specie. Alternatively, the flow rates can range from approximately 10 to approximately 100 sccm.

Additionally, the process chamber can be configured for a temperature ranging from about 10° to about 450° C. Alternatively, the chamber temperature can range from about 30° to about 60° C. The temperature for the plurality of substrates can range from approximately 10° to about 450° C. Alternatively, the substrate temperature can range form about 30° to about 60° C.

In 530, a thermal treatment process is performed to partially or fully remove the chemically altered oxide film on the plurality of substrates. The thermal treatment of the plurality of substrates may be performed during the chemical treatment of the plurality of substrates, or it may be performed following the chemical treatment of the plurality of substrates. When the thermal treatment is performed following the chemical treatment, a process gas, different from the process gas used during chemical treatment, may be used. The thermal treatment process can be conducted in the same processing chamber as the chemical treatment process or in a different processing chamber. For example, the process gas can include an inert gas, such as nitrogen or a Noble gas. Additionally, the process chamber can be configured for a temperature ranging from about 10° to about 450° C. Alternatively, the chamber temperature can range from about 50° to about 200° C. The temperature for the plurality of substrates can range from approximately 10° to about 450° C. Alternatively, the substrate temperature can range form about 50° to about 200° C. For example, the temperature of the plurality of substrates can exceed 100° C.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A processing system for etching an oxide film on a plurality of substrates, comprising:
a process chamber configured to contain said plurality of substrates, one or more of said plurality of substrates having said oxide film thereon;
a substrate holder coupled to said process chamber and configured to support said plurality of substrates;
a chemical treatment system coupled to said process chamber and configured to introduce a process gas comprising as an incipient ingredient HF to said process chamber, wherein said process gas chemically alters exposed surface layers on said plurality of substrates;
a thermal treatment system coupled to said process chamber and configured to elevate the temperature of said plurality of substrates, wherein said elevated temperature causes evaporation of said chemically altered surface layers; and
a controller configured to control the amount of said process gas introduced to said plurality of substrates, and the temperature to which said plurality of substrates are heated.

2. The processing system of claim 1, wherein said process chamber is configured to accommodate between 1 and 200 substrates.

3. The processing system of claim 1, wherein said process gas further includes as an incipient ingredient ammonia (NH₃).

4. The processing system of claim 3, wherein said chemical treatment system is further configured to supply a carrier gas with said process gas.

5. The processing system of claim 4, wherein said carrier gas comprises an inert gas.

6. The processing system of claim 5, wherein said inert gas comprises a Noble gas.

7. The processing system of claim 3, wherein said HF is introduced independently from said ammonia.

8. The processing system of claim 7, wherein said HF is introduced with argon.

9. The processing system of claim 1, wherein said substrate holder is translatable or rotatable, or both.

10. The processing system of claim 1, wherein said thermal treatment system comprises a multi-zone heating system.

11. The processing system of claim 1, wherein said controller is:
configured to monitor, adjust, or control the temperature of said plurality of substrates or an amount of said process gas in said process chambers, or any combination thereof.

12. The processing system of claim 1, wherein said oxide film on said plurality of substrates comprises silicon dioxide (SiO₂).

13. The processing system of claim 1, wherein said chemical treatment system comprises a multi-zone fluid distribution system configured to adjust the flow of said process gas to multiple zones within said process chamber.

14. A method of etching an oxide film on a plurality of substrates, comprising:
disposing said plurality of substrates in a batch processing system;
chemically treating said plurality of substrates by exposing said plurality of substrates to a gas composition comprising as an incipient ingredient HF; and
thermally treating said plurality of substrates by heating said plurality of substrates.

15. The method of claim 14, wherein said gas composition further includes as an incipient ingredient ammonia (NH₃).

16. A computer readable medium containing program instructions for execution on a substrate processing system, which when executed by the substrate processing system, cause the substrate processing system to perform the steps of:
disposing said plurality of substrates in a batch processing system;
chemically treating said plurality of substrates by exposing said plurality of substrates to a gas composition comprising as an incipient ingredient HF; and
thermally treating said plurality of substrates by heating said plurality of substrates.

15. The computer readable medium of claim 16, wherein said program instructions cause the substrate processing system to expose said substrates to said gas composition further including as an incipient ingredient ammonia (NH₃).
